(19) United States
(12) Patent Application Publication
(10) Pub. No.: US 2026/0123512 A1
(43) Pub. Date: Apr. 30, 2026

(54) Bonding pads for dies and electronic devices having the dies

(71) Applicant: REALTEK SEMICONDUCTOR CORPORATION, HSINCHU (TW)

(72) Inventor: NAI-JEN HSUAN, HSINCHU (TW)

(21) Appl. No.: 19/372,591

(22) Filed: Oct. 29, 2025

(30) Foreign Application Priority Data
Oct. 29, 2024 (TW) 113141338

(51) Int. Cl. H01L 23/00

(52) U.S. Cl. CPC H10W 72/90; H10W 72/50; H10W 72/932; H10W 72/9445; H10W 90/753

(57) ABSTRACT

An electronic device includes a carrier, a first die, and a second die. The first die is disposed on the carrier and includes a first bonding pad and a second bonding pad. The second die is disposed on the carrier and includes a third bonding pad and a fourth bonding pad. The first bonding pad is directly connected to the third bonding pad through a first bonding wire, and the second bonding pad is directly connected to the fourth bonding pad through a second bonding wire. The first bonding pad has a recessed space, and the second bonding pad is disposed in the recessed space.

### BACKGROUND OF THE INVENTION

### 1. Field of the Invention

The present invention generally relates to an electronic device, and more particularly, to a die and its bonding pad.

### 2. Description of Related Art

FIG. 1 shows a schematic diagram of the conventional die-to-die connection. FIG. 1 is a top view. The electronic device 100 includes a carrier 105, a die 110, and a die 120. The die 110 and the die 120 are disposed on the carrier 105. The die 110 and the die 120 transmit signals through the contact fingers 101 to 103. The contact fingers 101 to 103 are formed on the surface of the carrier 105. The bonding pads 111 to 113 are disposed on the surface of the die 110, while the bonding pads 121 to 123 are disposed on the surface of the die 120. The bonding pad 111 and the bonding pad 121 are connected through the contact finger 101. The bonding pad 112 and the bonding pad 122 are connected through the contact finger 102. The bonding pad 113 and the bonding pad 123 are connected through the contact finger 103.

In general, the contact finger 102 is used to transmit signals (e.g., single-ended signals or differential signals), while the contact finger 101 and the contact finger 103 are connected to a reference voltage (e.g., ground). However, implementing die-to-die communication through the contact fingers requires a larger area of the carrier 105, which is detrimental to the miniaturization and cost-effectiveness of the electronic device.

### SUMMARY OF THE INVENTION

In view of the issues of the prior art, an object of the present invention is to provide bonding pads for a die and an electronic device having the die, so as to make an improvement to the prior art.

According to one aspect of the present invention, a bonding pad is provided. The bonding pad is implemented on a die and includes a first segment, a second segment connected to the first segment, and a third segment connected to the first segment. The first segment, the second segment, and the third segment define a recessed space, and the recessed space is used to dispose of a signal pad.

According to another aspect of the present invention, an electronic device is provided. The electronic device includes a carrier, a first die disposed on the carrier and including a first bonding pad and a second bonding pad, and a second die disposed on the carrier and including a third bonding pad and a fourth bonding pad. The first bonding pad is directly connected to the third bonding pad through a first bonding wire, and the second bonding pad is directly connected to the fourth bonding pad through a second bonding wire. The first bonding pad has a recessed space, and the second bonding pad is disposed in the recessed space.

The technical means embodied in the embodiments of the present invention can solve at least one of the problems of the prior art. Therefore, compared to the prior art, the present invention contributes to the miniaturization and cost-effectiveness of an electronic device.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a schematic diagram of the conventional die-to-die connection.

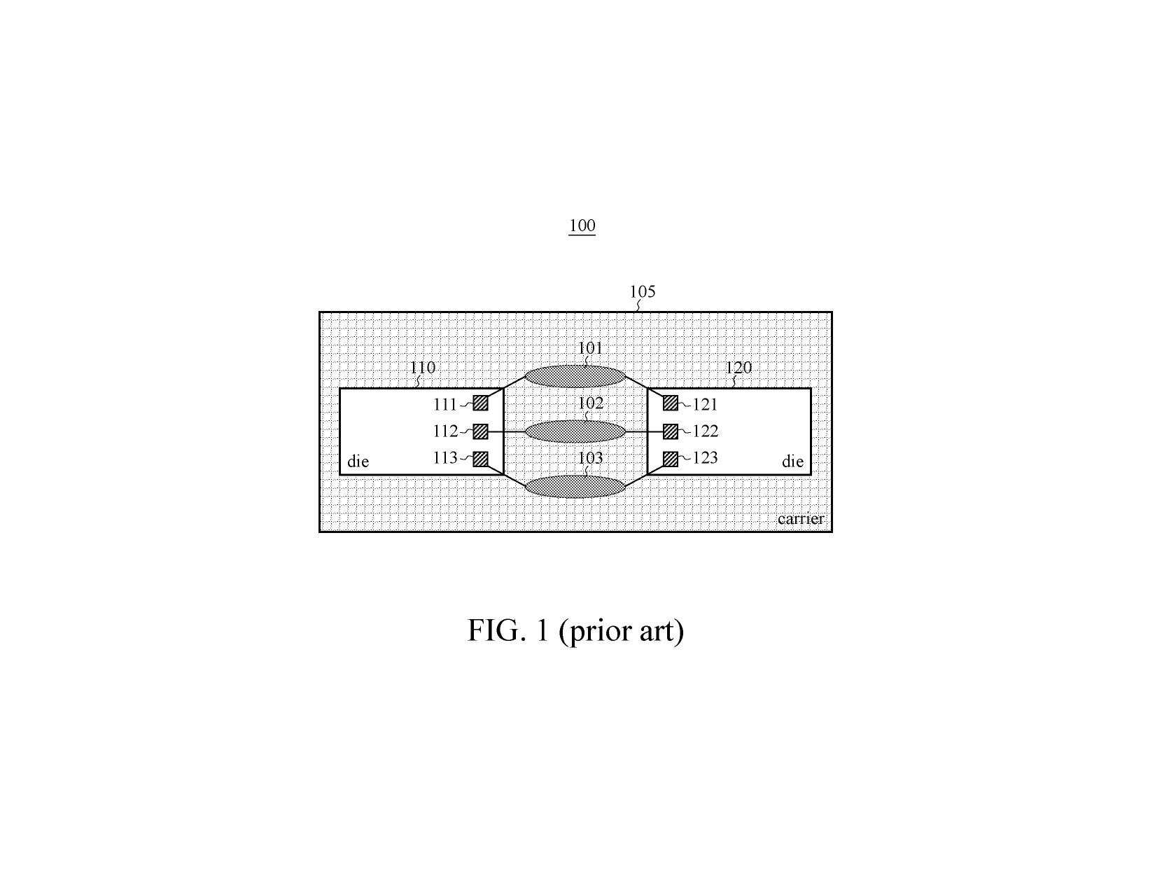

FIG. 2A is a top view of the electronic device according to an embodiment of the present invention.

FIG. 2B is a side view of the electronic device according to an embodiment of the present invention.

FIG. 3 shows the details of the bonding pad according to an embodiment of the present invention.

FIG. 4 is a cross-sectional view of a die according to an embodiment of the present invention.

FIG. 5 is a cross-sectional view of a die according to another embodiment of the present invention.

FIG. 6 shows the details of the bonding pad according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes bonding pads for a die and an electronic device having the die. On account of that some or all elements of the die and the electronic device could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

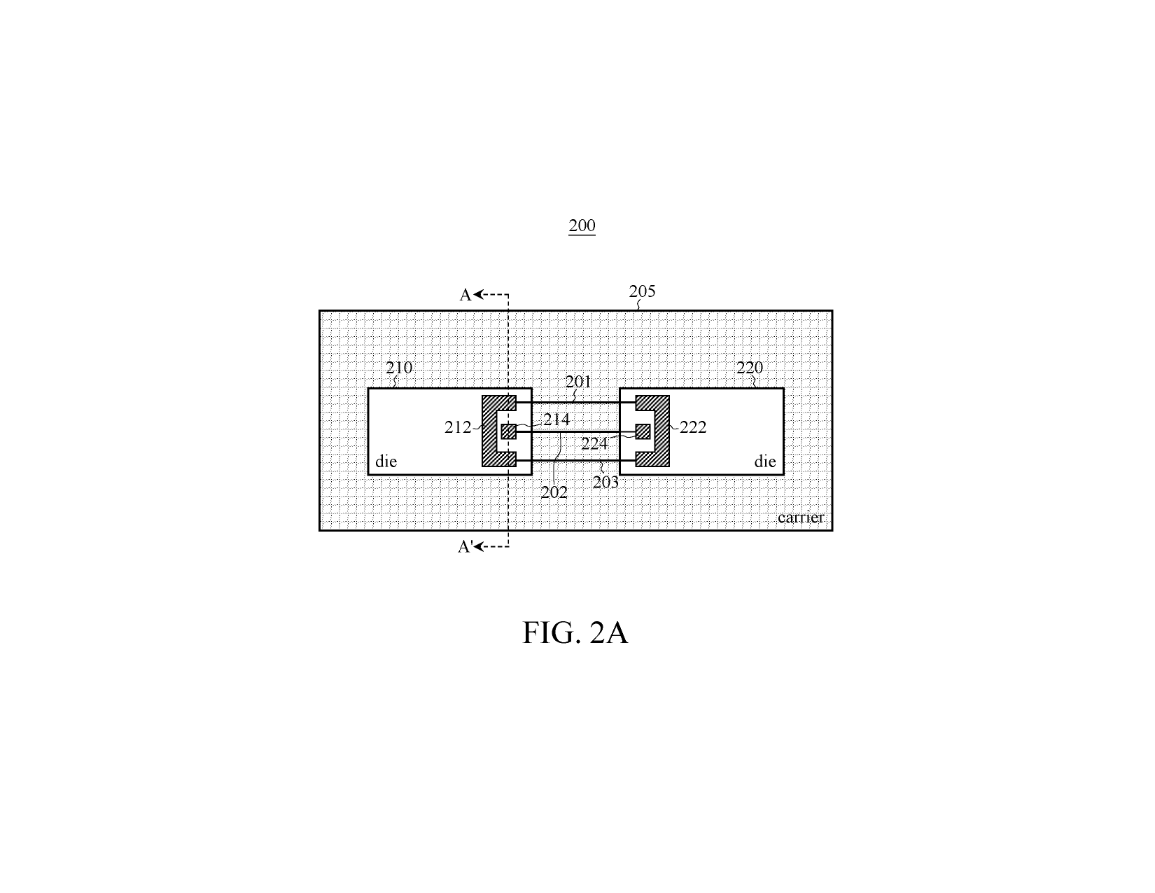

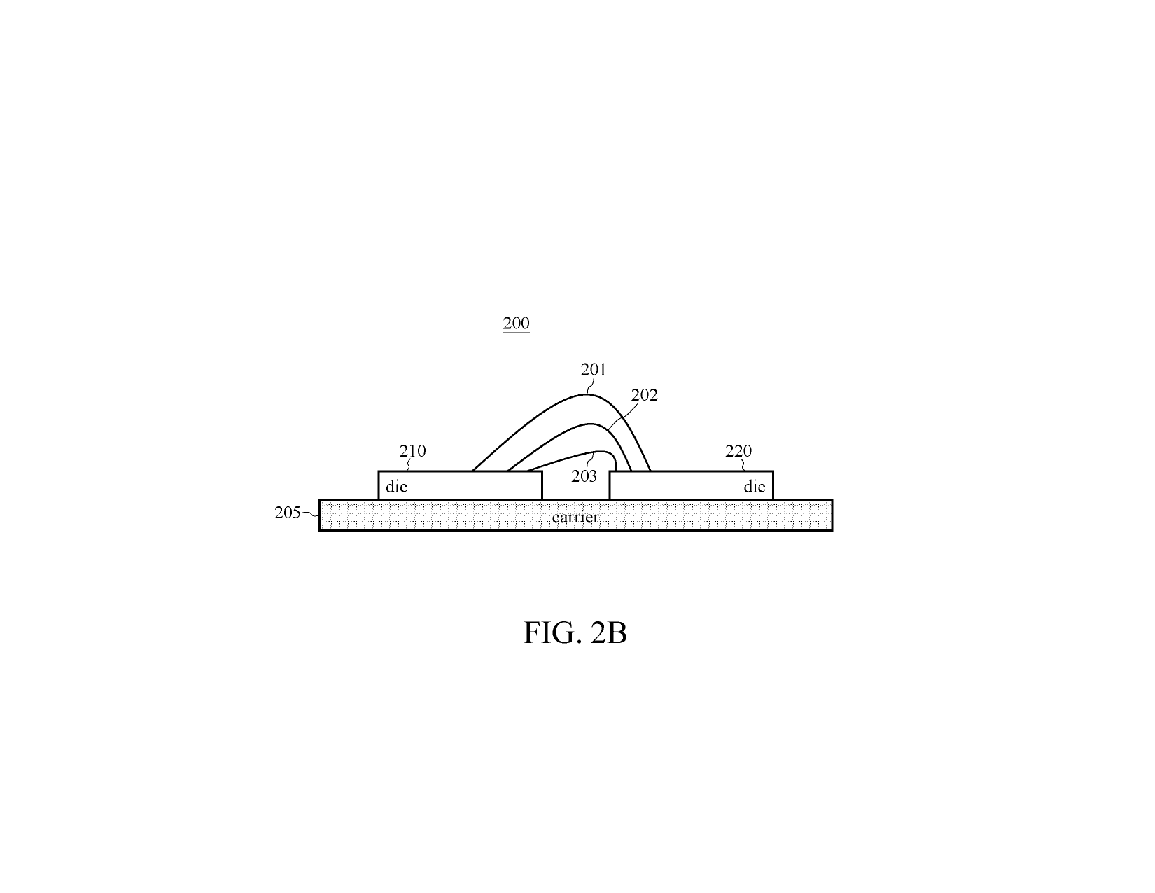

Reference is made to FIG. 2A and FIG. 2B. FIG. 2A is a top view of the electronic device according to an embodiment of the present invention, and FIG. 2B is a side view of the electronic device according to an embodiment of the present invention. The electronic device 200 includes a carrier 205, a die 210, and a die 220. The die 210 and the die 220 are disposed on the carrier 205. The bonding pad 212 and the bonding pad 214 are formed on the surface of the die 210. The bonding pad 222 and the bonding pad 224 are formed on the surface of the die 220. The bonding pad 212 and the bonding pad 222 are directly connected through the bonding wire 201 and the bonding wire 203. The bonding pad 214 is directly connected to the bonding pad 224 through the bonding wire 202. Here, “direct connection” means that when a signal is transmitted from the die 210 to the die 220, the signal does not pass through the carrier 205 or the contact fingers on it (if any). The direct communication method between the die 210 and the die 220 through multiple bonding wires can be referred to as internal bonding.

In some embodiments, the bonding wire 202 is used to transmit signals, while the bonding wire 201 and the bonding wire 203 are connected to the reference voltage (e.g., ground). Therefore, the bonding pad 214 and the bonding pad 224 can be referred to as the signal pad, and the bonding pad 212 and the bonding pad 222 can be referred to as the ground pad. Reference is made to FIG. 2B. In contrast to the electronic device 100, in the electronic device 200, the bonding wires 201 to 203 are not connected to the carrier 205. Therefore, the present invention reduces the demand for the carrier area, which contributes to the miniaturization and cost-effectiveness of the electronic device 200.

The bonding pad 212 provides signal protection (e.g., ground shielding) and/or signal reference for the bonding pad 214. The bonding pad 222 provides signal protection and/or signal reference for the bonding pad 224.

The bonding pad 212, the bonding pad 214, the bonding pad 222, and the bonding pad 224 are conductors. In some embodiments, the material of the bonding pads is a metal (including, but not limited to, aluminum, copper, gold) or an alloy.

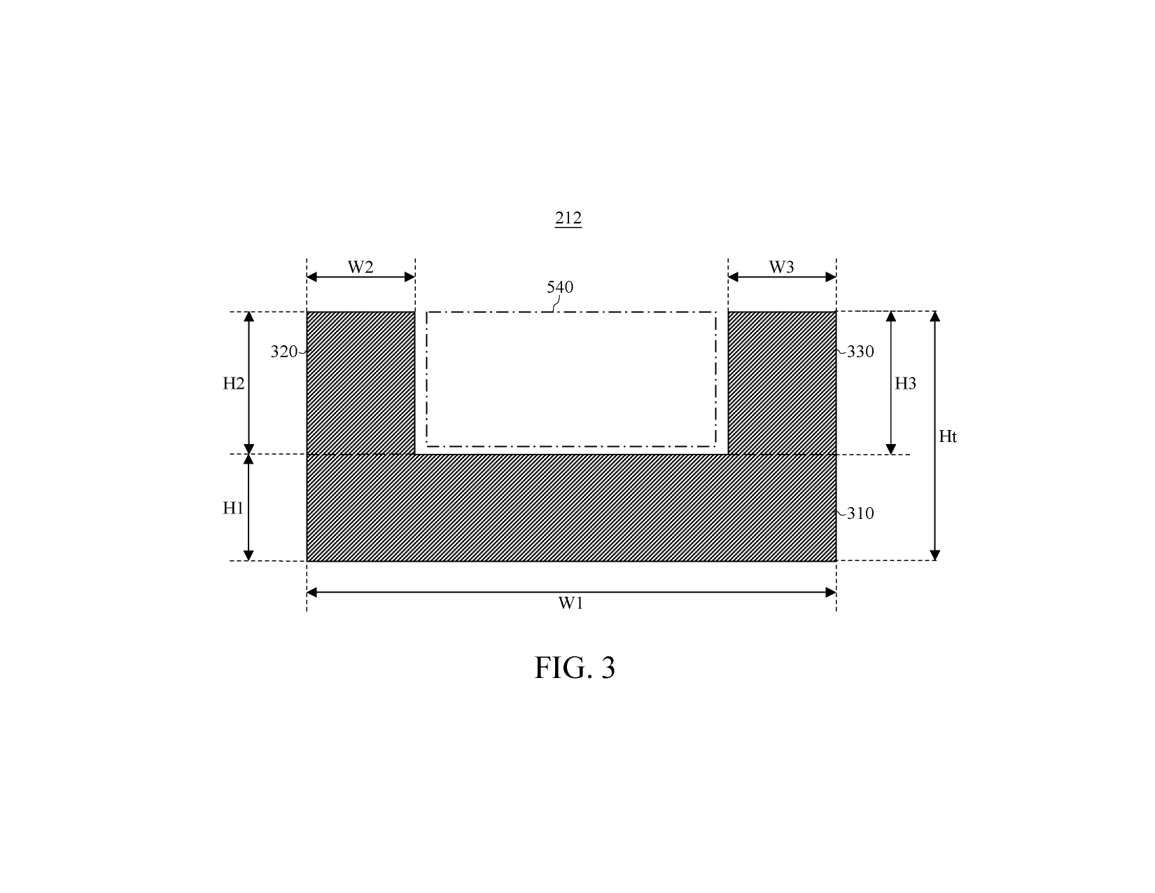

Reference is made to FIG. 3, which shows the details of the bonding pad 212 according to an embodiment of the present invention. The width and height of the bonding pad 212 are W1 and Ht, respectively. The bonding pad 212 includes the segment 310, the segment 320, and the segment 330.

The segment 310 is a rectangle. The width and height of the segment 310 are W1 and H1, respectively.

The segment 320 is a rectangle. The width and height of the segment 320 are W2 and H2, respectively.

The segment 330 is a rectangle. The width and height of the segment 330 are W3 and H3, respectively.

In some embodiments, the size of the segment 320 is substantially equal to the size of the segment 330. That is to say, the width W2 is substantially equal to the width W3, and the height H2 is substantially equal to the height H3.

In other embodiments, the width W2 is not equal to the width W3, and/or the height H2 is not equal to the height H3.

The bonding pad 212 has a recessed space 540. The recessed space 540 is defined by the segment 310, the segment 320, and the segment 330. More specifically, the width of the recessed space 540 is substantially equal to W1-W2-W3, and the height of the recessed space 540 is substantially equal to H2 or H3.

As shown in FIG. 3, the bonding pad 212 presents a “U” shape. In other embodiments, at least one of the segment 310, the segment 320, and the segment 330 is not a rectangle, but may be, for example, a trapezoid, a semicircle, a polygon, or an irregular shape.

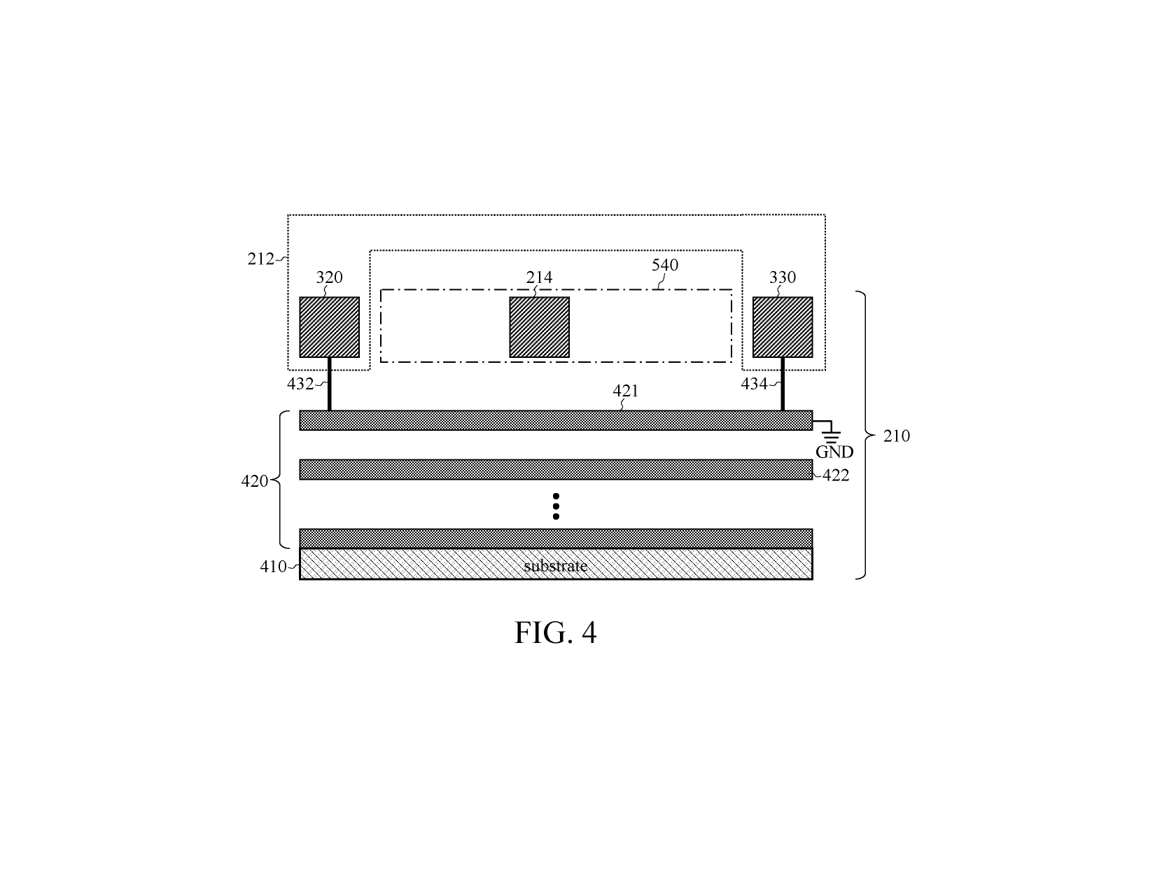

Reference is made to FIG. 4, which is a cross-sectional view of the die 210 according to an embodiment of the present invention. The cross-sectional view of FIG. 4 corresponds to the cross-section A-A' of FIG. 2A. The die 210 includes a substrate 410, a metal layer structure 420, the bonding pad 212, and the bonding pad 214. The metal layer structure 420 is disposed on top of the substrate 410 and contains multiple metal layers. The segment 320 of the bonding pad 212 is connected to the metal layer 421 through the internal connector 432 (e.g., a via hole or a through hole), and the segment 330 of the bonding pad 212 is connected to the metal layer 421 through the internal connector 434. The metal layer 421 is one of the metal layers of the metal layer structure 420 and is connected to the reference voltage GND (e.g., the ground). That is to say, the voltage on the bonding pad 212 is substantially equal to the reference voltage GND. In some embodiments, the bonding pad 214 can be connected to another metal layer (e.g., the metal layer 422) through an internal connector (not shown).

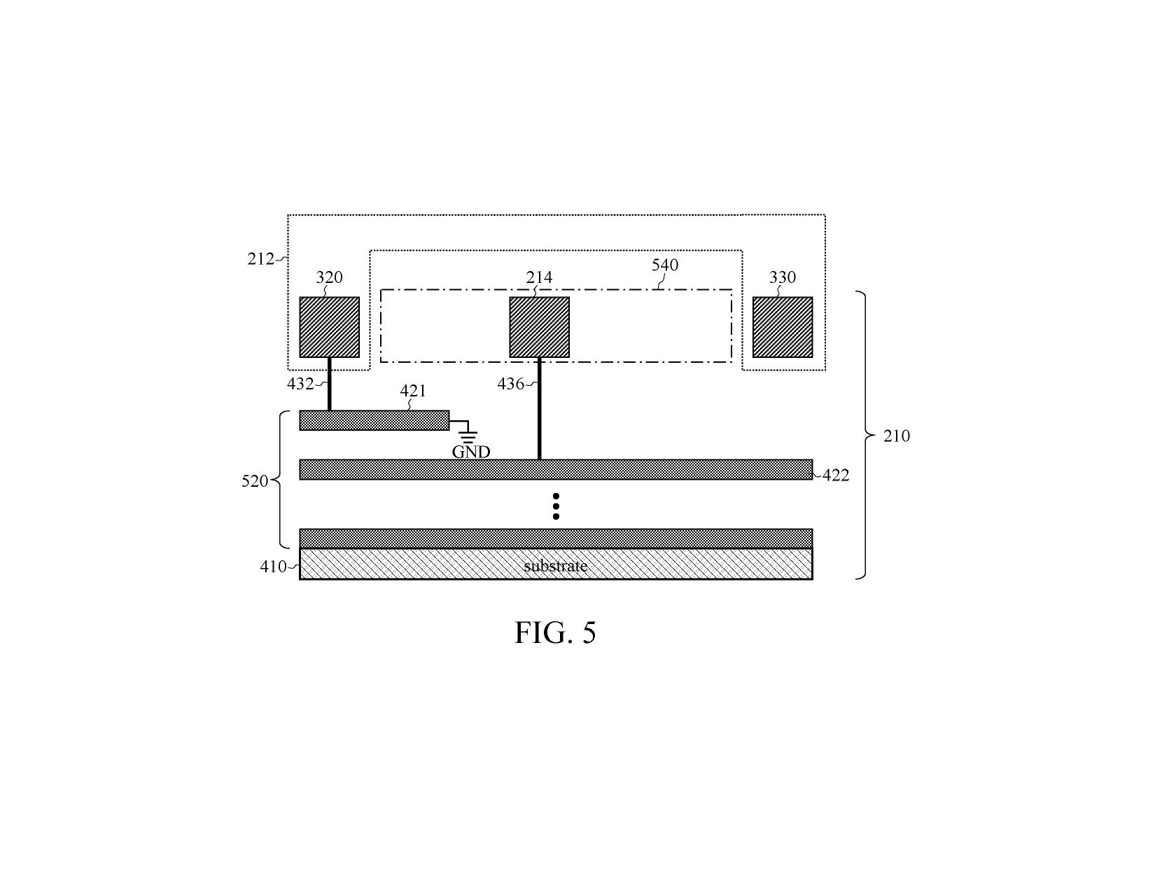

Reference is made to FIG. 5, which is a cross-sectional view of the die 210 according to another embodiment of the present invention. The cross-sectional view of FIG. 5 corresponds to the cross-section A-A' in FIG. 2A. The die 210 includes the substrate 410, the metal layer structure 520, the bonding pad 212, and the bonding pad 214. The metal layer 421 is one of the metal layers of the metal layer structure 520 and is connected to the reference voltage GND. The segment 320 of the bonding pad 212 is connected to the metal layer 421 through the internal connector 432, but the segment 330 of the bonding pad 212 is not connected to the metal layer structure 520 through any internal connector. The bonding pad 214 can be connected to another metal layer (e.g., the metal layer 422) through the internal connector 436.

Reference is made to FIG. 4 and FIG. 5. In FIG. 4, both ends of the bonding pad 212 (i.e., the segment 320 and the segment 330) are directly connected downward to the metal layer 421. However, in FIG. 5, the bonding pad 212 has only one end (e.g., the segment 320) directly connected downward to the metal layer 421, whereas the other end (e.g., the segment 330) is not directly connected downward to the metal layer 421. From FIG. 4 and FIG. 5, it can be seen that the present invention has considerable flexibility in the internal connections of the die 210, making it applicable to various semiconductor structures or circuit designs.

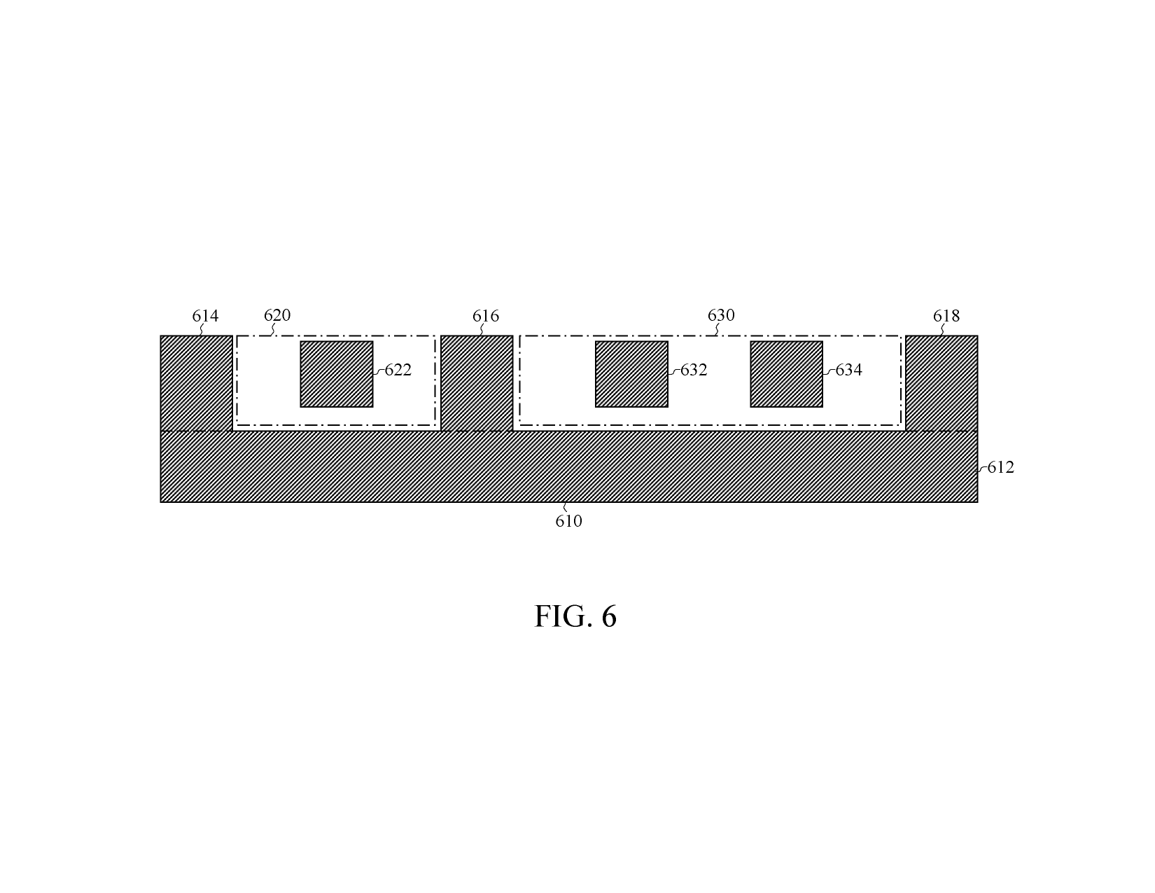

Reference is made to FIG. 6, which shows the details of the bonding pad according to another embodiment of the present invention. The bonding pad 610 includes the segment 612, the segment 614, the segment 616, and the segment 618, and has the recessed space 620 (which is defined by the segment 612, the segment 614, and the segment 616) and the recessed space 630 (which is defined by the segment 612, the segment 616, and the segment 618).

The bonding pad 622 is disposed in the recessed space 620. The bonding pad 632 and the bonding pad 634 are disposed in the recessed space 630. The bonding pad 610 is connected to the reference voltage GND (e.g., the bonding pad 610 may be a ground pad), and the bonding pad 622, the bonding pad 632, and the bonding pad 634 are used to transmit signals (i.e., these three bonding pad may be signal pads). In some embodiments, the bonding pad 622 is used to transmit single-ended signals, while the bonding pad 632 and the bonding pad 634 are used to transmit differential signals.

The bonding pad 610 provides signal protection and/or signal reference for the bonding pad 622, the bonding pad 632, and the bonding pad 634.

As shown in FIG. 6, the bonding pad 610 presents a combination of two “U” shapes. Similarly, in other embodiments, the segment 612, 614, 616, or 618 may be a shape other than a rectangle, such as a trapezoid, a semicircle, a polygon, or an irregular shape.

In summary, the present invention provides specially designed bonding pad on the surface of the die. Different from the conventional contact fingers, the present invention provides signal protection and/or signal reference directly on the die through a bonding pad. In addition, for the bonding pads that provide signal protection and/or signal reference (e.g., the bonding pad 212 or the bonding pad 610), it is sufficient that any part (e.g., a certain segment) is connected to the reference voltage GND, thereby increasing the flexibility of the circuit design.

The U-shape is intended to illustrate the invention by way of example and not to limit the scope of the claimed invention. People having ordinary skill in the art may apply the present invention to other shapes of bonding pad in accordance with the foregoing discussions.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A bonding pad implemented on a die and comprising:
a first segment;
a second segment connected to the first segment; and
a third segment connected to the first segment;
wherein the first segment, the second segment, and the third segment define a recessed space, and the recessed space is used to dispose of a signal pad.

2. The bonding pad of claim 1, wherein the signal pad is used to transmit a single-ended signal.

3. The bonding pad of claim 1, wherein the recessed space is a first recessed space, the signal pad is a first signal pad, and the bonding pad further comprises:
a fourth segment connected to the first segment;
wherein the first segment, the third segment, and the fourth segment define a second recessed space, and the second recessed space is used to dispose of a second signal pad and a third signal pad.

4. The bonding pad of claim 3, wherein the first signal pad is used to transmit a single-ended signal, and the second signal pad and the third signal pad are used to transmit a differential signal.

5. The bonding pad of claim 1, wherein a width of the first segment is W1, a width of the second segment is W2, a width of the third segment is W3, and a width of the recessed space is substantially equal to W1-W2-W3.

6. The bonding pad of claim 1, wherein a height of the second segment is H2, a height of the third segment is H3, and a height of the recessed space is substantially equal to H2 or H3.

7. The bonding pad of claim 6, wherein H2 is substantially equal to H3.

8. The bonding pad of claim 1, wherein the die comprises a metal layer structure, the metal layer structure comprises a metal layer connected to a reference voltage, and the second segment and the third segment are both connected to the metal layer.

9. The bonding pad of claim 1, wherein the die comprises a metal layer structure, the metal layer structure comprises a metal layer connected to a reference voltage, and only one of the second segment and the third segment is directly connected to the metal layer.

10. An electronic device, comprising:
a carrier;
a first die disposed on the carrier and including a first bonding pad and a second bonding pad; and
a second die disposed on the carrier and including a third bonding pad and a fourth bonding pad;
wherein the first bonding pad is directly connected to the third bonding pad through a first bonding wire, and the second bonding pad is directly connected to the fourth bonding pad through a second bonding wire;
wherein the first bonding pad has a recessed space, and the second bonding pad is disposed in the recessed space.

11. The electronic device of claim 10, wherein the first bonding pad comprises:
a first segment;
a second segment connected to the first segment; and
a third segment connected to the first segment;
wherein the first segment, the second segment, and the third segment define the recessed space.

12. The electronic device of claim 11, wherein the second bonding pad is used to transmit a single-ended signal.

13. The electronic device of claim 11, wherein the recessed space is a first recessed space, and the first bonding pad further comprises:
a fourth segment connected to the first segment;
wherein the first segment, the third segment, and the fourth segment define a second recessed space, and the second recessed space is used to dispose of a fifth bonding pad and a sixth bonding pad.

14. The electronic device of claim 13, wherein the second bonding pad is used to transmit a single-ended signal, and the fifth bonding pad and the sixth bonding pad are used to transmit a differential signal.

15. The electronic device of claim 11, wherein a width of the first segment is W1, a width of the second segment is W2, a width of the third segment is W3, and a width of the recessed space is substantially equal to W1-W2-W3.

16. The electronic device of claim 11, wherein a height of the second segment is H2, a height of the third segment is H3, and a height of the recessed space is substantially equal to H2 or H3.

17. The electronic device of claim 16, wherein H2 is substantially equal to H3.

18. The electronic device of claim 11, wherein the first die comprises a metal layer structure, the metal layer structure comprises a metal layer connected to a reference voltage, and the second segment and the third segment are both connected to the metal layer.

19. The electronic device of claim 11, wherein the first die comprises a metal layer structure, the metal layer structure comprises a metal layer connected to a reference voltage, and only one of the second segment and the third segment is directly connected to the metal layer.
